(19) United States
(12) Patent Application Publication
(10) Pub. No.: US 2008/0001525 A1
(43) Pub. Date: Jan. 3, 2008

(54) Arrangements of color pixels for full color OLED

(75) Inventors: Ching-Ian Chao, Hsinchu (TW); Yuan-Chun Wu, Taoyuan (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: AU Optronics Corporation, Hsinchu (TW)

(21) Appl. No.: 11/478,921

(22) Filed: Jun. 30, 2006

(51) Int. Cl. H05B 33/00; H01L 51/50

(52) U.S. Cl. 313/500; 313/505; 313/503

(57) ABSTRACT

A color display panel formed with a plurality of pixels in a matrix with a row direction and a column direction, wherein each pixel comprises a first sub-pixel, a second sub-pixel and a third sub-pixel adjacently aligned along the row direction of the pixel matrix, and a red light emission zone, a green light emission zone and a blue light emission zone. In one embodiment, the color display panel comprises an arrangement of the red, green and blue light emission zones of a pixel in a triangle with the geometrical center of each emission zone located at a respective vertex of the triangle such that one side of the triangle is substantially parallel to one of the row direction and the column direction, thereby in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

### FIELD OF THE INVENTION

The present invention relates generally to a full color display, and more particularly, to an organic light emitting diode display device with arrangements of sub-pixels.

### BACKGROUND OF THE INVENTION

Generally, a full color display panel is composed of red, green and blue sub-pixel devices, arranged in a stripe form, a mosaic form or a delta form, so as to provide full color effects by mixing the light of these colors emitted from the individual sub-pixel devices in the display panel. Due to its compact size, high resolution, low power consumption, self-emission and fast response, organic light emitting diode (OLED) display panels have widespreadly been used for high definition displays of full color images.

Conventionally, an arrangement of the red, green and blue sub-pixel devices of liquid crystal displays is employed for OLED display panels, which is shown in FIGS. 6a and 6b. In this arrangement, each pixel 601 in the pixel matrix 600 has a first, second and third sub-pixels 610, 620 and 630 that are adjacently aligned in the row direction of the pixel matrix 600, and red, green and blue sub-pixel devices 650, 660 and 670 that are arranged in the first, second and third sub-pixels 610, 620 and 630, respectively, along the row direction of the pixel matrix 600. As such, two adjacent sub-pixel devices in the row direction define a gap having a distance, Lr, and two adjacent sub-pixel devices in the column direction define a gap having a distance, Lc, which is much greater than the distance Lr, as shown in FIG. 6a.

Such an arrangement of the sub-pixel devices may pose a considerable level of difficulty in the display panel manufacturing process. For example, in the manufacture of full-color OLED display panels, a shadow mask alignment method is generally utilized to form the individual red, green and blue sub-pixel devices through deposition of respective organic layers on a substrate of the display panel. The resolution of an OLED display panel depends on the opening dimensions of the shadow mask. For the arrangement of the sub-pixel devices shown in FIG. 6a, the distance Lr between two adjacent sub-pixel devices in the row direction is significantly less than the distance Lc between two adjacent sub-pixels in the column direction. Accordingly, the alignment tolerance of a sub-pixel device in the row direction, Lr/2, is much less than the alignment tolerance of a sub-pixel device in the column direction, Lc/2 in the display panel manufacturing process. This may cause misalignment of the sub-pixel devices in the OLED display panels. An example of the sub-pixel device misalignment is shown in FIG. 6b. Misalignment in the sub-pixel devices results in problems such as no deposition of the organic layer and thus the short-circuiting of the lower electrode and the upper electrode of the sub-pixel device, and deposition of the organic layer in an adjacent sub-pixel, which causes mixing of colors or non-emission of light. The arrangement of the sub-pixel devices also makes fabricating a shadow mask very difficult. In addition, it is hard to manufacture a high-resolution OLED display using the arrangement of the sub-pixel devices.

Therefore, a heretofore unaddressed need exists in the art to address the aforementioned deficiencies and inadequacies.

### SUMMARY OF THE INVENTION

The present invention, in one aspect, relates to a display panel capable of displaying a color image. In one embodiment, the display panel includes a plurality of pixels formed in a matrix with a row direction and a column direction. Each pixel has a first sub-pixel, a second sub-pixel and a third sub-pixel adjacently aligned along the row direction of the matrix, and a first light emission zone, a second light emission zone and a third light emission zone arranged in a triangle with the geometrical center of each emission zone located at a respective vertex of the triangle such that one side of the triangle is substantially parallel to one of the row direction and the column direction, wherein each of the first light emission zone, thet second light emission zone and the third light emission is capable of emitting light in a unique color. As arranged in the matrix of the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

In one embodiment, each of the first light emission zone, the second light emission zone and the third light emission zone comprises a corresponding one of a red light emission zone, a green light emission zone and a blue light emission zone. Each of the red, green and blue light emission zones has a width in the row direction and a length in the column direction, where the width and the length of each of the red, green and blue light emission zones are different or substantially identical. In one embodiment, the geometrical center of each of the red, green and blue light emission zones is located in a corresponding sub-pixel of the first, second and third sub-pixels, and of the pixel, respectively, such that the one side of the triangle is substantially parallel to the row direction. In another embodiment, the geometrical center of one of the red, green and blue light emission zones is located in one of the first and third sub-pixels of the pixel, and the geometrical centers of the rest of the red, green and blue light emission zones are located in the other of the first and third sub-pixels of the pixel, respectively, such that the one side of the triangle is substantially parallel to the column direction.

Each of the red, green and blue light emission zones comprises a light emitting diode device capable of emitting light in a respective color of red, blue and green colors. In one embodiment, the light emitting diode device includes an organic light emitting diode (OLED) device or a plurality of OLED devices connected in series. Each OLED device comprises a top-emission OLED device or a bottom-emission OLED device. Additionally, the OLED device may have a normal structure or an inverted structure.

The display panel further comprises a driving circuit to individually drive the red, green and blue light emission zones of each of the plurality of pixels to emit light of corresponding colors therefrom. In one embodiment, the driving circuit is formed such that the display panel corresponds to one of a passive matrix OLED device and an active matrix OLED device.

In another aspect, the present invention relates to a display panel capable of displaying a color image, formed with a plurality of pixels in a matrix with a row direction and a column direction, where each pixel comprises a first sub-pixel, a second sub-pixel and a third sub-pixel adjacently aligned along the row direction of the matrix, and a red light emission zone, a green light emission zone and a blue light emission zone. In one embodiment, the display panel comprises an arrangement of the red, green and blue light emission zones of a pixel in a triangle with the geometrical center of each emission zone located at a respective vertex of the triangle such that one side of the triangle is substantially parallel to one of the row direction and the column direction, thereby in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction. Each of the red, green and blue light emission zones comprises a light emitting diode device capable of emitting light in a respective color of red, blue and green colors.

In one embodiment, the geometrical center of each of the red, green and blue light emission zones is located in a corresponding sub-pixel of the first, second and third sub-pixels, and of the pixel, respectively, such that the one side of the triangle is substantially parallel to the row direction. In another embodiment, the geometrical center of one of the red, green and blue light emission zones is located in one of the first and third sub-pixels of the pixel, and the geometrical centers of the rest of the red, green and blue light emission zones are located in the other of the first and third sub-pixels of the pixel, respectively, such that the one side of the triangle is substantially parallel to the column direction.

In yet another aspect, the present invention relates to a method for forming a display panel for displaying a color image, where the display panel has a plurality of pixels in the form of a matrix with a row direction and a column direction, and wherein each pixel comprises a first sub-pixel, a second sub-pixel and a third sub-pixel adjacently aligned along the row direction of the matrix, and a red light emission zone, a green light emission zone and a blue light emission zone. In one embodiment, the method includes the step of arranging the red, green and blue light emission zones of a pixel in a triangle with the geometrical center of each light emission zone located at a respective vertex of the triangle such that one side of the triangle is substantially parallel to one of the row direction and the column direction, thereby in the matrix of the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction. Each of the red, green and blue light emission zones comprises a light emitting diode device capable of emitting light in a respective color of red, blue and green colors.

In a further aspect, the present invention relates to a display panel capable of displaying a color image, comprising a plurality of pixels formed in a matrix with a row direction and a column direction. In one embodiment, each pixel includes a first sub-pixel, a second sub-pixel and a third sub-pixel; and a first light emission zone, a second light emission zone and a third light emission zone arranged in a triangle with the geometrical center of each emission zone located at a respective vertex of the triangle such that one side of the triangle is substantially parallel to one of the row direction and the column direction, wherein each of the first light emission zone, the second light emission zone and the third light emission is capable of emitting light in a unique color. In one embodiment, each of the first light emission zone, the second light emission zone and the third light emission zone comprises a corresponding one of a red light emission zone, a green light emission zone and a blue light emission zone.

As arranged in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

In yet a further aspect, the present invention relates to a three-color pixel element for a display. In one embodiment, the three-color pixel element has a first sub-pixel, a second sub-pixel and a third sub-pixel adjacently aligned in a pixel of matrix with a row direction and a column direction, and a first light emission zone, a second light emission zone and a third light emission zone arranged in a triangle with the geometrical center of each emission zone located at a respective vertex of the triangle such that one side of the triangle is substantially parallel to one of the row direction and a column direction perpendicular to the row direction, where any two adjacent light emission zones of different colors in the row direction define a gap having a first distance, and any two adjacent light emission zones of different colors in the column direction define a gap having a second distance, and wherein the first distance and the second distance are substantially or nearly same. Each of the first light emission zone, the second light emission zone and the third light emission is capable of emitting light in a unique color.

In one aspect, the present invention relates to a full color display made from the three-color pixel element as disclosed above.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIGS. 1a-1c show schematically a unit of different arrangements of the red, green and blue light emission zones according to different embodiments of the present invention, respectively.

FIGS. 2a-2d show schematically an arrangement of red, green and blue light emission zones according to different embodiments of the present invention, respectively: FIG. 2a, a unit of the arrangement, FIG. 2b, one embodiment of the arrangement, FIG. 2c, another embodiment of the arrangement, and FIG. 2d, an extended portion of the arrangement of FIG. 2b.

FIGS. 3a-3d show schematically an arrangement of red, green and blue light emission zones according to different embodiments of the present invention, respectively: FIG. 3a, a unit of the arrangement, FIG. 3b, one embodiment of the arrangement, FIG. 3c, another embodiment of the arrangement, and FIG. 3d, an extended portion of the arrangement of FIG. 3b.

FIGS. 4a and 4b show two layouts of an arrangement of the red, green and blue light emission zones according to one embodiment of the present invention.

FIGS. 5a-5d show schematically an arrangement of red, green and blue light emission zones according to different embodiments of the present invention, respectively: FIG. 5a, a unit of the arrangement, FIG. 5b, one embodiment of the arrangement, FIG. 5c, another embodiment of the arrangement, and FIG. 5d, an extended portion of the arrangement of FIG. 5b.

FIGS. 6a and 6b show a conventional stripe arrangement of the red, green and blue light emission zones and an image of the arrangement in an OLED display panel, respectively.

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise.

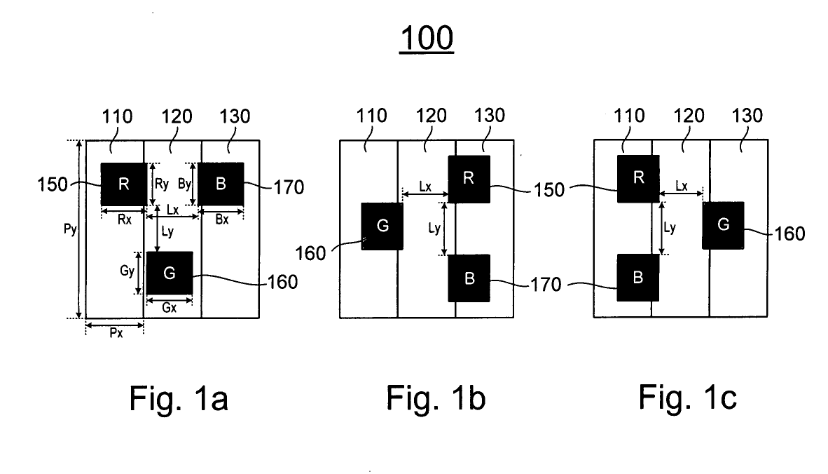

The description will be made as to the embodiments of the present invention in conjunction with the accompanying drawings in FIGS. 1-5. In accordance with the purposes of this invention, as embodied and broadly described herein, this invention, in one aspect, relates to a full color display panel with arrangements of sub-pixel emission devices.

The full color display panel has a plurality of pixels formed in a matrix with a row direction and a column direction that is perpendicular to the row direction. Referring to FIGS. 1a-1c, each pixel 100 in the matrix of the plurality of pixels includes a first sub-pixel 110, a second sub-pixel 120 and a third sub-pixel 130 that are adjacently aligned along the row direction of the pixel matrix. Each sub-pixel 110, 120, or 130 is substantially identical to each other and has a sub-pixel pitch, Px, in the row direction and a sub-pixel pitch, Py, in the column direction. Both the sub-pixel pitch Px in the row direction and the sub-pixel pitch Py in the column direction of a sub-pixel define an area of the sub-pixel, i.e., (Px×Py).

Furthermore, each pixel 100 has a red light (sub-pixel) emission zone 150, a green light (sub-pixel) emission zone 160 and a blue light (sub-pixel) emission zone 170 that are arranged in a triangle in which the geometrical center of each emission zone 150, 160, or 170 is located at a respective vertex of the triangle. As such, one side of the triangle is substantially parallel to the row direction or the column direction. In one embodiment, the geometrical center R, G, or B of each light emission zone 150, 160, or 170 is located in a respective sub-pixel of the first, second and third sub-pixels 110, 120, and 130 of the pixel 100, and the emission zone in the second sub-pixel 120 is shifted by a distance, Ly, from the emission zones in the first and third emission zones 110 and 130 in the column direction, such that the one side of the triangle formed by the emission zones in the first and third emission zones 110 and 130 is substantially parallel to the row direction. In addition, the distance Lx between the two emission zones in the first and third emission zones 110 and 130 in the row direction is substantially or nearly the same as the distance Ly. For example, as shown in FIG. 1a, the geometrical centers R, G and B of the red, green and blue light emission zones 150, 160 and 170 are located in the first, second and third sub-pixels 110, 120, and 130, respectively. The green light emission zone 160 is shifted by the distance Ly from the red and blue light emission zones 150 and 170 in the column direction. In this arrangement, the side of the triangle formed by the red and blue light emission zones 150 and 170 is substantially parallel to the row direction, and the distance Lx between the red and blue light emission zones 150 and 170 is same as or approximate to the distance Ly.

In another embodiment, the geometrical center of one of the red, green and blue light emission zones 150, 160 and 170 is located in one of the first and third sub-pixel 110 and 130 of the pixel 100, and the geometrical centers of the rest of the red, green and blue light emission zones 150, 160, and 170 are located in the other of the first and third sub-pixel 110 and 130 of the pixel 100, such that the one side of the triangle is substantially parallel to the column direction. As shown in FIGS. 1b, the geometrical center G of the green light emission zone 160 is located in the first sub-pixel 110, and the geometrical centers R and B of the red light emission zone 150 and the blue light emission zone 170 are located in the third sub-pixel 130. While in FIG. 1c the geometrical center G of the green light emission zone 160 is located in the third sub-pixel 130, and the geometrical centers R and B of the red light emission zone 150 and the blue light emission zone 170 are located in the first sub-pixel 110. In the arrangements of the red, green and blue light emission zones 150, 160, and 170 shown in FIGS. 1b and 1c, the green light emission zone 160 is shifted by a distance, Lx, from the red and blue light emission zones 150 and 170 in the row direction, and the side of the triangle formed by the red light emission zone 150 and the blue light emission zone 170 is substantially parallel to the column direction. The distance Lx is same as or approximate to a distance, Ly, defined between the red and blue light emission zones 150 and 170 in the column direction.

Each of the red, green, and blue light emission zones 150, 160, and 170 may be formed in any geometrical shape, such as square, rectangle, circle, triangle, trapezoid, polygon, or any combinations thereof. Preferably, the red, green and blue light emission zones 150, 160, and 170 have a geometrical shape of a square and/or rectangle, as shown in FIGS. 1a-1c. In general, each of the red, green, and blue light emission zones 150, 160, and 170 can be characterized with a width, Rx, Gx, or Bx, in the row direction and a length, Ry, Gy, or By, in the column direction. The width and the length, Rx and Ry, Gx and Gy, or Bx and By, of each of the red, green and blue light emission zones 150, 160, and 170 can be different or substantially identical. Therefore, an aperture ratio for each of the red, green, and blue light emission zones 150, 160, and 170 is defined by (Rx×Ry)/[(Px×Py)], (Gx×Gy)/[(Px×Py)] or (Bx×By)/[(Px×Py)], where (Rx×Ry), (Gx×Gy), (Bx×By) and (Px×Py) are an area of the red, green, and blue light emission zones 150, 160, and 170 and a sub-pixel 110, 120, or 130, respectively. Compared with the conventional arrangements of the sub-pixel emission zones, the invented arrangements of the red, green, and blue sub-pixel emission zones promise larger aperture ratios, which are necessary for prolonging the life time of a display panel. In addition, the arrangements also ensure to reduce the level of difficulty in the manufacturing process, and provide larger tolerance for preventing from color mixing during the process of fabricating the full-color OLED display panel.

Preferably, each of the red, green, and blue light emission zones 150, 160, and 170 is corresponding to a light emitting diode device capable of emitting light in a respective color of red, blue, and green colors. The light emitting diode device may include an OLED device or a plurality of OLED devices connected in series, where each OLED device can be a top-emission OLED device or a bottom-emission OLED device. Additionally, the OLED device may have a normal structure or an inverted structure.

Without intent to limit the scope of the invention, exemplary embodiments of the arrangements of the sub-pixel emission devices in an OLED display panel are described below.

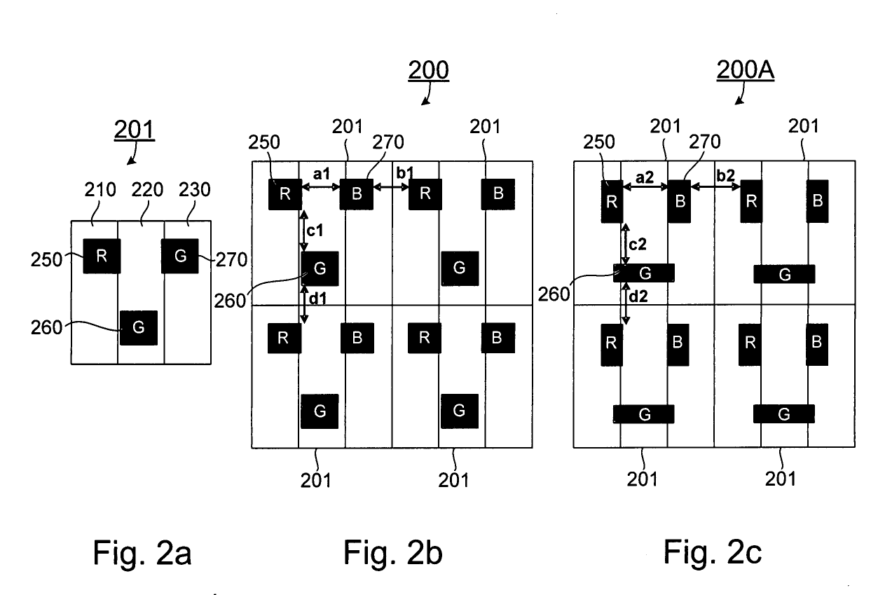

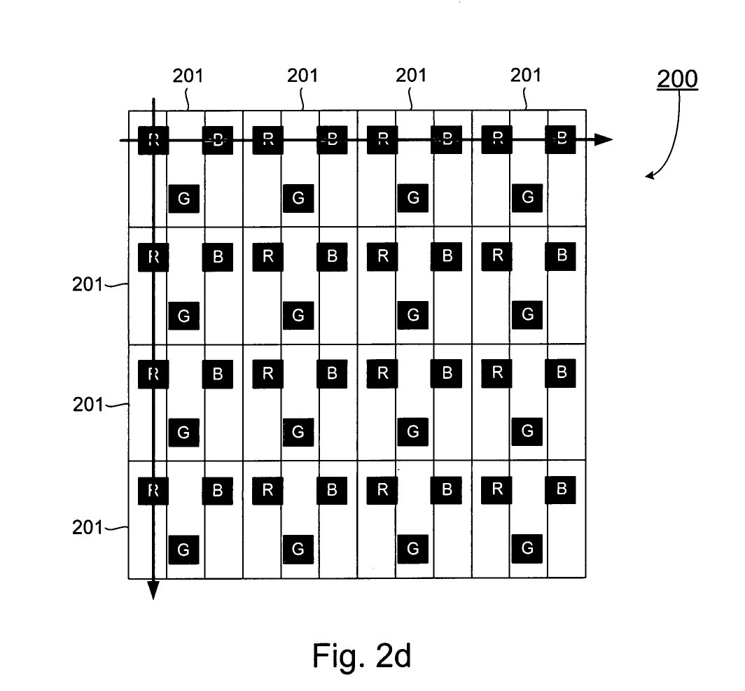

FIG. 2b shows an embodiment of a color pixel arrangement in an OLED display panel in which a unit of the arrangement of the red, green and blue sub-pixel emission devices 250, 260 and 270 shown in FIG. 2a (and also in FIG. 1a) is repeated for each pixel 201 in the pixel matrix. In the arrangement 200 of FIG. 2b, each of the red, green, and blue sub-pixel emission devices 250, 260, and 270 has a geometrical shape of square. Any two adjacent light emission devices of different colors in the row direction define a gap having a distance, e.g., the red and blue light emission devices 250 and 270 of a pixel 201 are separated by a distance, a1, and the blue light emission device 270 of the pixel 201 and the red light emission device 250 of the adjacent pixel 201 in the row direction are separated by a distance, b1, where b1 is equal or approximate to a1. And any two adjacent light emission zones of different colors in the column direction define a gap having a distance. For example, the red (blue) light emission device 250 (270) and the green light emission device 260 of a pixel 201 are separated by a distance, c1, and the green light emission device 260 of the pixel 201 and the red (blue) light emission device 250 (270) of the adjacent pixel 201 in the column direction are separated by a distance, d1, that is equal or approximate to c1. As shown in FIG. 2b, a1 and/or b1 are substantially or nearly the same as c1 and/or d1. FIG. 2d shows an extended portion of the pixel matrix of the color pixel arrangement 200 shown in FIG. 2b. The color pixel arrangement 200 is corresponding to a stripe arrangement.

FIG. 2c shows an embodiment of a color pixel arrangement 200A in an OLED display panel in which the arrangement unit of the red, green, and blue sub-pixel emission devices 250, 260, and 270 shown in FIG. 2a (and also in FIG. 1a) is repeated for each pixel 201 in the pixel matrix. But each of the red, green, and blue sub-pixel emission devices 250, 260, and 270 in the embodiment has a geometrical shape of rectangle. As shown in FIG. 2c, in this arrangement 200A, the width Rx (Bx) of the red (blue) light emission device 250 (270) in the row direction is less than the length Ry (By) of the red (blue) light emission device 250 (270) in the column direction. While for the green light emission device 260, the width Gx is greater than the length Gy. Similarly, any two adjacent light emission devices of different colors in the row direction define a gap having a distance, such as a2 and b2 with a2≅b2, any two adjacent light emission zones of different colors in the column direction define a gap having a distance, e.g., c2 and d2 with c2≅d2, as shown in FIG. 2c. Preferably, a2 and b2 are substantially or nearly the same as c2 and d2.

In one embodiment, the gap distances, an, bn, cn, dn, satisfy the relationships of 20 μm ≦an, bn, cn, dn≦60 μm, and 0.2(an+bn+cn+dn)≦an, bn, cn, dn≦0.3(an+bn+cn+dn), where n=1 or 2.

In practice, a driving circuit is required to individually drive the red, green, and blue light emission devices 250, 260, and 270 of each of the plurality of pixels to emit light of corresponding colors therefrom. The driving circuit can be formed in a passive matrix addressing manner or an active matrix addressing manner. The former is corresponding to a passive matrix OLED device, while the latter an active matrix OLED device.

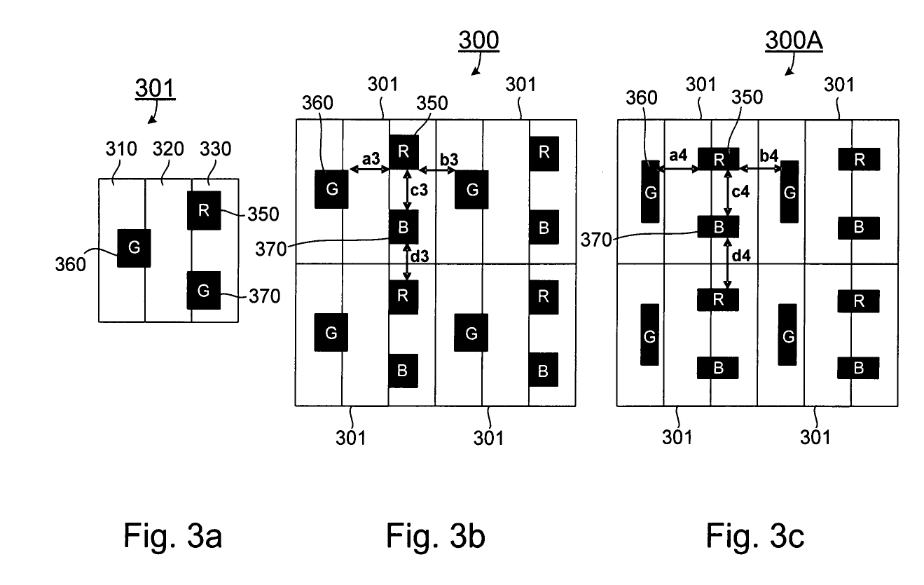

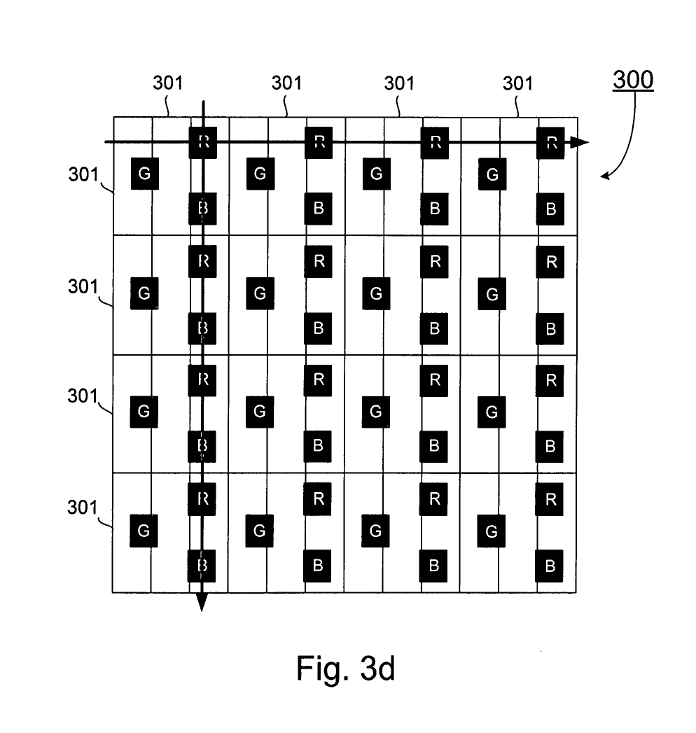

Referring to FIGS. 3b-3d, embodiments of a color pixel arrangement in an OLED display panel in which a unit of the arrangement of the red, green, and blue sub-pixel emission devices 350, 360, and 370 shown in FIG. 3a (and also in FIG. 1b) is repeated for each pixel 301 in the pixel matrix are shown. In the arrangements 300 and 300A shown in FIGS. 3b and 3c, respectively, each of the red, green, and blue sub-pixel emission devices 350, 360, and 370 has a geometrical shape of square (FIGS. 3b) or rectangle (FIG. 3c). The green light emission device 360 and the red (blue) light emission device 350 (370) of a pixel 301 are separated by a distance, a3 (FIG. 3b) or a4 (FIG. 3c). While the red (blue) light emission device 350 (370) of the pixel 301 and the green light emission device 360 of the adjacent pixel 301 in the row direction are separated by a distance, b3 (FIG. 3b) or b4 (FIG. 3c), where a3≅b3 (FIG. 3b) and a4≅b4 (FIG. 3c). In the column direction, a distance, c3 (FIG. 3b) or c4 (FIG. 3c), between the red and blue light emission devices 350 and 370 of the pixel 301 and a distance, d3 (FIG. 3b) or d4 (FIG. 3c), between the blue light emission device 370 of the pixel 301 and the red light emission device 350 of the adjacent pixel 301 are also substantially or nearly same. Furthermore, all the distances satisfy the relationship of a3≅b3≅c3≅d3 (FIG. 3b) or a4≅b4≅c4≅d4 (FIG. 3c). In one embodiment, each of the distances an, bn, cn, dn is in a range of about 20-60 μm, and greater than 0.2(an+bn+cn+dn) but less than 0.3(an+bn+cn+dn), where n=3 or 4.

FIG. 3d shows an extended portion of the pixel matrix of the color pixel arrangement 300 in the OLED display panel shown in FIG. 3b. The color pixel arrangement 300 is also corresponding to a stripe arrangement.

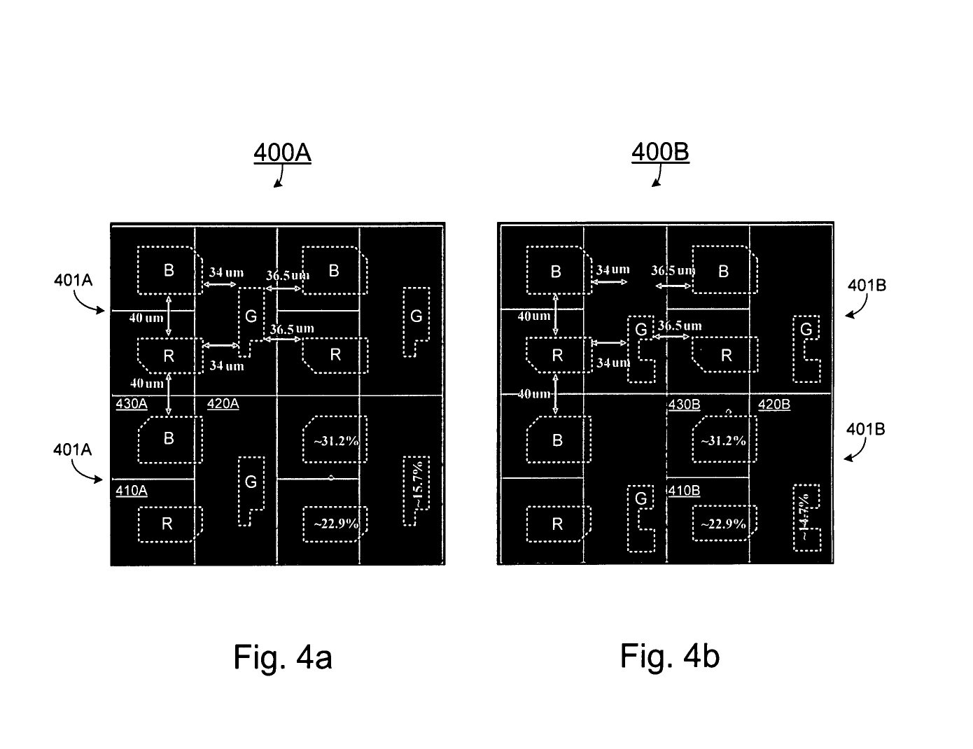

TABLE 1
The aperture ratio and the alignment tolerance for the
conventional stripe format and the invented arrangement
of the red, green and blue sub-pixel devices.

| | | | | Tolerance (um) | |
|---|---|---|---|---|---|
| | Aperture ratio (%) | | | X (in | Y (in the |
| | | Green | | the row | column |
| Pixel Format | Red (B) | (G) | Blue (B) | direction) | direction) |
| Stripe | 17.8 | 13.2 | 26 | ±15 | ±15 |
| The invented | 22.9 | 15.7 | 31.2 | ±17 | ±20 |
| arrangement | | | | | |
| shown in FIG. 4a | | | | | |
| The invented | 22.9 | 14.7 | 31.2 | ±17 | ±20 |
| arrangement | | | | | |
| shown in FIG. 4b | | | | | |

FIGS. 4a and 4b show two pixel layouts 400A and 400B of a 2.4″ OLED display panel according to embodiments of the present invention, respectively. In the pixel layout 400A, a pixel unit 401A has a first sub-pixel 410A, a second sub-pixel 420A, and a third sub-pixel 430A that are aligned adjacently to each other. The pixel unit 401A also includes a red OLED device R, a green OLED device G, and a blue OLED device B arranged in a triangle such that the OLED devices R, B and G are located in the sub-pixel 410A, 420A, and 430A, respectively. Similarly, in the pixel layout 400B, a pixel unit 401B has a first sub-pixel 410B, a second sub-pixel 420B, and a third sub-pixel 430B aligned adjacently to each other, and a red OLED device R, a green OLED device G, and a blue OLED device B arranged in a triangle such that the OLED devices R, B and G are located in the sub-pixel 410B, 420B, and 430B, respectively. The aperture ratio and the alignment tolerance for the conventional stripe format and the invented arrangement of the red, green and blue sub-pixel devices are listed in Table 1. The advantages of the present invention over the conventional stripe format are clearly exhibited in the table. For example, compared to the conventional stripe format, the alignment tolerances in the invented pixel layouts 400A and 400B increase about 2 μm in the row direction (X) and about 5 um in the column direction (Y). The aperture ratio averagely increases about 21%, therefore the lifetime of the display panel would increase about 30% for the color pixel arrangement of the present invention.

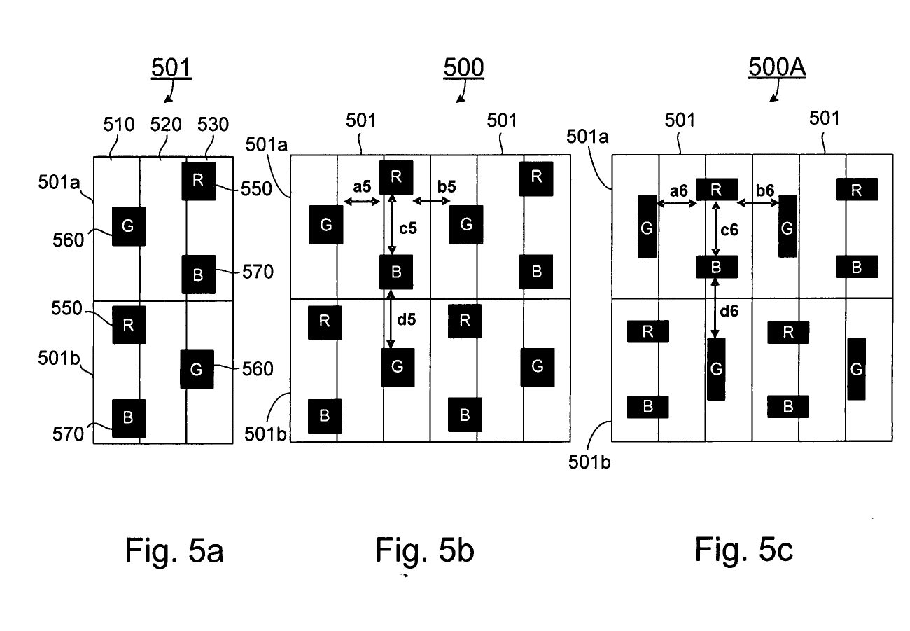

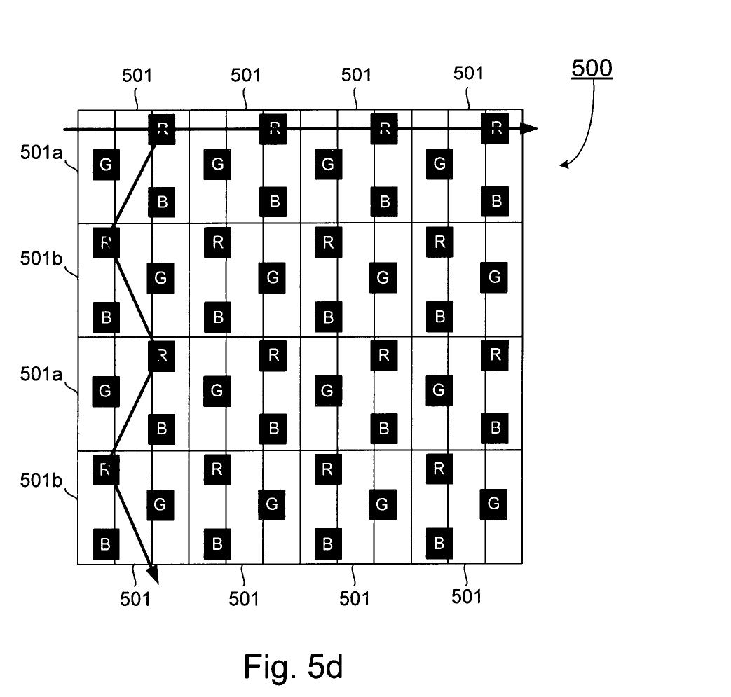

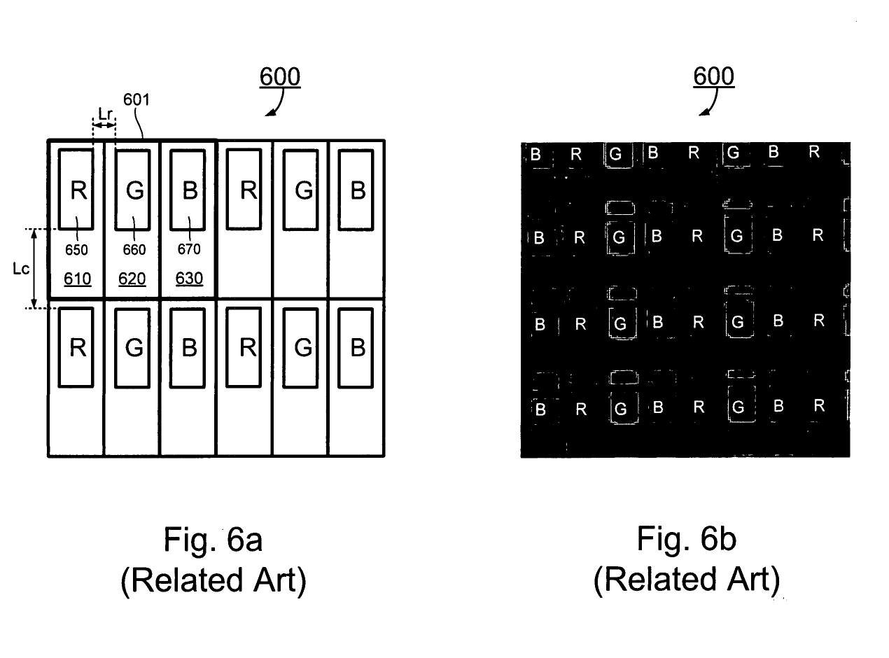

Referring now to FIGS. 5a-5d, alternative embodiments of the color pixel arrangement according to the present invention are shown. FIG. 5a shows an arrangement unit 501 that is a combination of the arrangements of FIGS. 1b and 1c. The arrangement unit 501 comprises two adjacent pixels 501a and 501b along the column direction. The red, green, and blue light emission devices 550, 560, and 570 are arranged in the triangle shown in FIG. 1b in pixel 501 a, and in the triangle shown in FIG. 1c in pixel 501b. By repeating the arrangement unit 501 in every two adjacent pixels along the column direction for each column of the pixel matrix, the color pixel arrangements 500 and 500A in a full color OLED display panel are implemented, which are shown in FIGS. 5b and 5c, respectively. In the color pixel arrangements 500, each of the red, green, and blue light emission devices 550, 560, and 570 has a geometrical shape of square, while it is geometrically a rectangle in the color pixel arrangements 500A. The geometrical shape of square or rectangle for each of the red, green and blue light emission devices 550, 560, and 570 can be substantially identical or different.

As shown in FIGS. 5b and 5c, any two adjacent light emission devices of different colors in the row direction are separated by an approximately identical distance, e.g., a5 (a6) and b5 (b6) are the distances between the green and red light emission devices 560 and 550, and the red and adjacent green light emission devices 550 and 560, respectively, and a5≅b5 (FIG. 5b) and a6≅b6 (FIG. 5c). Any two adjacent light emission devices of different colors in the column direction are also separated by an approximately identical distance, for example, the distances between the red and blue light emission devices 550 and 570, and the blue and green light emission devices 570 and 560 are c5 (c6) and d5 (d6), respectively, which c5≅d5 (FIG. 5b) and c6≅d6 (FIG. 5c). Furthermore, the separated distances in the row and column directions are also substantially or nearly same, i.e., a5≅b5≅c5≅d5 (FIG. 5b) or a6≅b6≅c6≅d6 (FIG. 5c). In one embodiment, 20 μm≦an, bn, cn, dn≦60 μm, and 0.2(an+bn+cn+dn)≦an, bn, cn, dn≦0.3(an+bn+cn+dn), where n=5 or 6.

FIG. 5d shows an extended portion of the pixel matrix 500 of the color pixel arrangement 500 in the OLED display panel shown in FIG. 5b. The color pixel arrangement 500 is corresponding to a delta arrangement format.

In the embodiments of the present invention as disclosed above, the red, green and blue light emission devices in an OLED display panel are arranged in a triangle such that any two adjacent light emission zones of different colors in the row direction define a gap having a first distance, and any two adjacent light emission zones of different colors in the column direction define a gap having a second distance that is substantially or nearly the same as the first distance. Such arrangement of the light emission devices ensure to reduce the level of difficulty in the manufacturing process, particularly in the shadow mask process, a standard manufacturing process of OLED display panels.

Another aspect of the present invention provides a method for displaying a color image in a display panel. The display panel is formed with a plurality of pixels in a matrix along a row direction and a column direction, where each pixel comprises a first sub-pixel, a second sub-pixel and a third sub-pixel adjacently aligned along the row direction of the pixel matrix, and a red light emission zone, a green light emission zone, and a blue light emission zone. In one embodiment, the method includes the step of arranging the red, green, and blue light emission zones of a pixel in a triangle with the geometrical center of each light emission zone located at a respective vertex of the triangle such that one side of the triangle is substantially parallel to one of the row direction and the column direction, thereby in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

While in the foregoing description of the exemplary embodiments of the invention, colors red, green and blue have been chosen to describe various embodiments of the present invention as no limiting examples. The present invention can be practiced with a first sub-pixel, a second sub-pixel, a third sub-pixel, or a plurality of a light emission zones, each having a color such as brown, yellow, pink, violet, indigo, reddish orange, orange, cyan, salmon pink, mauve, or the like to form a display panel the can display a color image.

Thus, the foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A display panel capable of displaying a color image, comprising a plurality of pixels formed in a matrix with a row direction and a column direction, each pixel comprising:
a. a first sub-pixel, a second sub-pixel and a third sub-pixel adjacently aligned along the row direction of the matrix; and
b. a first light emission zone, a second light emission zone and a third light emission zone arranged in a triangle with the geometrical center of each emission zone located at a respective vertex of the triangle such that one side of the triangle is substantially parallel to one of the row direction and the column direction, wherein each of the first light emission zone, the second light emission zone and the third light emission is capable of emitting light in a unique color,
wherein as arranged in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

2. The display panel of claim 1, wherein each of the first light emission zone, the second light emission zone and the third light emission zone comprises a corresponding one of a red light emission zone, a green light emission zone and a blue light emission zone.

3. The display panel of claim 2, wherein the geometrical center of each of the red, green and blue light emission zones is located in a corresponding sub-pixel of the first, second and third sub-pixels, and of the pixel, respectively, such that the one side of the triangle is substantially parallel to the row direction.

4. The display panel of claim 2, wherein the geometrical center of one of the red, green and blue light emission zones is located in one of the first and third sub-pixels of the pixel, and the geometrical centers of the rest of the red, green and blue light emission zones are located in the other of the first and third sub-pixels of the pixel, respectively, such that the one side of the triangle is substantially parallel to the column direction.

5. The display panel of claim 2, wherein each of the red, green and blue light emission zones has a width in the row direction and a length in the column direction.

6. The display panel of claim 5, wherein the width and the length of each of the red, green and blue light emission zones are different or substantially identical.

7. The display panel of claim 2, wherein each of the red, green and blue light emission zones comprises a light emitting diode device capable of emitting light in a respective color of red, blue and green colors.

8. The display panel of claim 7, wherein the light emitting diode device comprises an organic light emitting diode (OLED) device or a plurality of OLED devices connected in series.

9. The display panel of claim 8, wherein each OLED device comprises one of a top-emission OLED device and a bottom-emission OLED device.

10. The display panel of claim 8, wherein each OLED device has one of a normal structure and an inverted structure.

11. The display panel of claim 8, further comprising a driving circuit to individually drive the red, green and blue light emission zones of each of the plurality of pixels to emit light of corresponding colors therefrom.

12. The display panel of claim 11, wherein the driving circuit is formed such that the display panel corresponds to one of a passive matrix OLED device and an active matrix OLED device.

13. A display panel capable of displaying a color image, formed with a plurality of pixels in a matrix with a row direction and a column direction, wherein each pixel comprises a first sub-pixel, a second sub-pixel and a third sub-pixel adjacently aligned along the row direction of the matrix, and a red light emission zone, a green light emission zone and a blue light emission zone, comprising:
an arrangement of the red, green and blue light emission zones of a pixel in a triangle with the geometrical center of each emission zone located at a respective vertex of the triangle such that one side of the triangle is substantially parallel to one of the row direction and the column direction, thereby in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

14. The display panel of claim 13, wherein the geometrical center of each of the red, green and blue light emission zones is located in a corresponding sub-pixel of the first, second and third sub-pixels, and of the pixel, respectively, such that the one side of the triangle is substantially parallel to the row direction.

15. The display panel of claim 13, wherein the geometrical center of one of the red, green and blue light emission zones is located in one of the first and third sub-pixels of the pixel, and the geometrical centers of the rest of the red, green and blue light emission zones are located in the other of the first and third sub-pixels of the pixel, respectively, such that the one side of the triangle is substantially parallel to the column direction.

16. The display panel of claim 13, wherein each of the red, green and blue light emission zones has a width in the row direction and a length in the column direction.

17. The display panel of claim 16, wherein the width and the length of each of the red, green and blue light emission zones are different or substantially identical.

18. The display panel of claim 13, wherein each of the red, green and blue light emission zones comprises a light emitting diode device capable of emitting light in a respective color of red, blue and green colors.

19. The display panel of claim 18, wherein the light emitting diode device comprises an organic light emitting diode (OLED) device or a plurality of OLED devices connected in series.

20. The display panel of claim 19, wherein each OLED device comprises one of a top-emission OLED device and a bottom-emission OLED device.

21. The display panel of claim 19, wherein each OLED device has one of a normal structure and an inverted structure.

22. A method for forming a display panel for displaying a color image, wherein the display panel has a plurality of pixels in a matrix with a row direction and a column direction, and wherein each pixel comprises a first sub-pixel, a second sub-pixel and a third sub-pixel adjacently aligned along the row direction of the matrix, and a red light emission zone, a green light emission zone and a blue light emission zone, comprising the step of:
arranging the red, green and blue light emission zones of a pixel in a triangle with the geometrical center of each light emission zone located at a respective vertex of the triangle such that one side of the triangle is substantially parallel to one of the row direction and the column direction, thereby in the matrix of the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

23. The method of claim 22, wherein the geometrical center of each of the red, green and blue light emission zones is located in a corresponding sub-pixel of the first, second and third sub-pixels, and of the pixel, respectively, such that the one side of the triangle is substantially parallel to the row direction.

24. The method of claim 22, wherein the geometrical center of one of the red, green and blue light emission zones is located in one of the first and third sub-pixels of the pixel, and the geometrical centers of the rest of the red, green and blue light emission zones are located in the other of the first and third sub-pixels of the pixel, respectively, such that the one side of the triangle is substantially parallel to the column direction.

25. The method of claim 22, wherein each of the red, green and blue light emission zones comprises a light emitting diode device capable of emitting light in a respective color of red, blue and green colors.

26. The method of claim 25, wherein the light emitting diode device comprises an organic light emitting diode (OLED) device or a plurality of OLED devices connected in series.

27. A display panel capable of displaying a color image, comprising a plurality of pixels formed in a matrix with a row direction and a column direction, each pixel comprising:
a. a first sub-pixel, a second sub-pixel and a third sub-pixel; and
b. a first light emission zone, a second light emission zone and a third light emission zone arranged in a triangle with the geometrical center of each emission zone located at a respective vertex of the triangle such that one side of the triangle is substantially parallel to one of the row direction and the column direction, wherein each of the first light emission zone, the second light emission zone and the third light emission is capable of emitting light in a unique color,
wherein as arranged in the plurality of pixels, any two adjacent light emission zones of different colors in the row direction define a gap having a distance, and any two adjacent light emission zones of different colors in the column direction define a gap having a distance that is substantially or nearly the same as the distance of the gap defined between two adjacent light emission zones of different colors in the row direction.

28. The display panel of claim 27, wherein each of the first light emission zone, the second light emission zone and the third light emission zone comprises a corresponding one of a red light emission zone, a green light emission zone and a blue light emission zone.

29. A three-color pixel element for a display, comprising:
a. a first sub-pixel, a second sub-pixel and a third sub-pixel adjacently aligned in a pixel of a matrix with a row direction and a column direction;
b. a first light emission zone, a second light emission zone and a third light emission zone arranged in a triangle with the geometrical center of each emission zone located at a respective vertex of the triangle such that one side of the triangle is substantially parallel to one of the row direction and a column direction perpendicular to the row direction, wherein each of the first light emission zone, the second light emission zone and the third light emission is capable of emitting light in a unique color,
wherein any two adjacent light emission zones of different colors in the row direction define a gap having a first distance, and any two adjacent light emission zones of different colors in the column direction define a gap having a second distance, and wherein the first distance and the second distance are substantially or nearly same.

30. A full color display made from the three-color pixel element of claim 29.
